(19) United States
(12) Patent Application Publication
(10) Pub. No.: US 2008/0292993 A1
(43) Pub. Date: Nov. 27, 2008

(54) PHOTO-CATIONIC POLYMERIZABLE EPOXY RESIN COMPOSITION, LIQUID DISCHARGE HEAD, AND MANUFACTURING METHOD THEREOF

(75) Inventors: Hiroe Ishikura, Kawasaki-shi (JP); Shoji Shiba, Kawasaki-shi (JP); Shinsuke Tsuji, Kawasaki-shi (JP); Akihiko Okano, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/954,689

(22) Filed: Dec. 12, 2007

(30) Foreign Application Priority Data
Dec. 22, 2006 (JP) 2006-346267

(51) Int. Cl. G03F 7/20; C08K 5/34; C08K 5/45; C08K 5/28; B41J 2/105

(52) U.S. Cl. 430/320; 522/75; 522/78; 347/20

(57) ABSTRACT

A liquid discharge head having a substrate provided with energy generating elements for generating energy to discharge a liquid, discharge portions including discharge ports for discharging the liquid, and flow paths supplying the liquid to the discharge portions and a method for its manufacture are provided. The method includes the steps of forming a layer of a negative type photosensitive resin on the substrate, and exposing the layer to light having a wavelength of 365 nm to form the discharge portions.

### BACKGROUND OF THE INVENTION

1. Field of the Invention

The present invention relates to an epoxy resin composition including an epoxy resin compound, a photo acid generator, and at least one other ingredient. More specifically, it relates to a photo-cationic polymerizable epoxy resin composition, which is suitable for forming microstructures on a substrate by a photolithographic process. In addition, the present invention also relates to a liquid discharge head in which a flow path forming member is formed using the photo-cationic polymerizable epoxy resin composition and a method for manufacturing the liquid discharge head.

2. Description of the Related Art

In recent years, concomitant with ever accelerating developments in science and technology, there has been an increase in demand for microstructures in various fields. Research has been actively carried out in the fields of microactuators, electronic devices, optical devices, and the like. The formation of a pattern by photolithography using a photosensitive resin material has advantages such as an ability to provide a superior shape with a high aspect ratio at a high level of accuracy.

When the above microstructure is formed, and in particular, when a structure to be used as a component is formed on a substrate, a negative type photosensitive resin material is primarily used. Furthermore, in accordance with the purpose of use, when the structure is required to have a chemical resistance or is required to have a relatively large film thickness on the order of several micrometers to several tens of micrometers, a photo-cationic polymerizable photosensitive resin material composed primarily of an epoxy resin has been actively investigated.

When a microstructure is formed using an epoxy-based photosensitive resin material, a photo-cationic polymerizable epoxy resin composition is used that is composed of a cationic polymerizable epoxy resin or an epoxy oligomer and a photo-cationic polymerization initiator, such as a photo acid generator. The formation of the microstructure using the above photo-cationic polymerizable epoxy resin composition is performed as described below. When exposure is performed for the photo-cationic polymerizable epoxy resin composition, an acid is generated by the photo acid generator. Subsequently, by performing post-exposure baking (hereinafter referred to as “PEB” in some cases), open-ring polymerization of an epoxy group proceeds using the acid as a catalyst, and as a result, exposed parts are cured. Next, by developing, a microstructure having a desired pattern shape can be obtained (hereinafter, the process from the exposure to the development described above will be called “patterning” in some cases”). In the case described above, because of various factors, such as diffusion of the acid to non-exposed parts, basic components in air, and/or the conditions of a surface with which the resin is in contact, patterning properties may sometimes be detrimentally influenced. As a result, resolution properties and/or dimensional controllability may be reduced and a desired shape may not be obtained. In particular, when patterning is performed using a photo-cationic polymerizable epoxy resin composition, in general, the film thereof is formed on a substrate and is then exposed. However, as shown in FIG. 3, due to light reflected from a substrate 1, a dull foot corner 100 is undesirably formed. FIG. 3 is a cross-sectional view of a cured photo-cationic polymerizable epoxy resin composition patterned on the substrate, and light is irradiated in the direction indicated by the arrow. The dotted lines indicate an originally intended pattern. Reference numeral 200 indicates the cured product. In addition, when the process from the PEB to the development is not smoothly performed, the acid diffuses to a part of the resin that has not been exposed. As a result, the dull foot corner as described above may also be formed.

In order to solve the problems described above, for example, a method has been proposed in Japanese Patent Laid-Open No. 5-127369 and U.S. Pat. Nos. 5,580,695 and 5,981,139, in which a material that decreases the effect of an acid is incorporated in a photosensitive resin to prevent unnecessarily diffusion of the acid generated into an exposed part.

However, the negative type photosensitive resin as described above is a resin used in the manufacturing of a semiconductor integrated circuit. Hence, when a microstructure is formed on a substrate, the above negative type photosensitive resin is not sufficient for the following reasons:

Chemical resistance is inferior.

Mechanical strength is inferior.

A usable film thickness is approximately 1 μm, and it is difficult to obtain a thick film.

A basic material is used in a semiconductor process, and hence, when the negative type photosensitive resin is volatile, the production line may become contaminated.

In addition, for manufacturing semiconductor elements or the like, line width patterning on a submicron level or smaller is required. Accordingly, satisfactory pattern formation cannot be performed by an exposure apparatus using the conventional g line or the g+h line as a light source.

In addition, when a light source having a short wavelength region is used for the exposure, since the absorption by a common photosensitive resin composition is excessively high, the selection range of materials is reduced. Furthermore, when a material sensitive to a light source having a short wavelength region of 200 nm or less is used, a problem in terms of material stability may arise. Hence, a search for a manufacturing process using the i-line as an exposure light source has commenced in order to form a fine element. In addition, in view of this research, a photosensitive resin composition having a high resolution is needed.

A practical example of a microstructure formed from a photo-cationic polymerizable epoxy resin composition as described above is a liquid discharge head used, for example, in an inkjet recording device.

In the field of liquid discharge heads, as disclosed in U.S. Pat. No. 4,657,631, a photo-cationic polymerizable epoxy resin may be used for a flow path forming member, which forms discharge ports, and flow paths communicating therewith. In recent years, there has been a trend leading to a decrease in the size of a discharge droplet. As a result, there is an increasing need to attain stability in the discharge direction. In addition, in order to maintain a stable discharge state, a so-called tapered discharge portion is desired in which a flow path gradually narrows as it approaches a discharge port.

For the above-described reasons, a photo-cationic polymerizable epoxy resin used for forming a liquid discharge head is required to have excellent resolution properties and shape controllability at a large film thickness of several micrometers to several tens of micrometers, which is a thickness typically used for the liquid discharge head.

### SUMMARY OF THE INVENTION

Accordingly, the present invention provides a photo-cationic polymerizable epoxy resin composition, which does not generate dull foot corners described above even at a large film thickness of several micrometers to several tens of micrometers and which can form a tapered shape with a good level of accuracy. In addition, the present invention also provides a photo-cationic polymerizable epoxy resin composition, which has superior storage stability and which can be easily handled while still maintaining the above-described properties. Furthermore, the present invention also provides a method for manufacturing a liquid discharge head using the resin composition as described above.

In accordance with one aspect of the present invention, there is provided a method for manufacturing a liquid discharge head that has a substrate provided with energy generating elements generating energy used to discharge a liquid; discharge portions each including a discharge port for discharging the liquid; and flow paths supplying the liquid to the discharge portions. The method comprises the steps of: forming a layer of a negative type photosensitive resin on the substrate; and exposing the layer to light having a wavelength of 365 nm to form the discharge portions. In the method described above, the negative type photosensitive resin includes an epoxy resin, a photo-cationic polymerization initiator, and a polycyclic aromatic compound including an atom having a non-covalent electron pair, which is directly bonded to an aromatic ring or which is incorporated into a heterocyclic ring.

In addition, in accordance with another aspect of the present invention, there is provided a photo-cationic polymerizable epoxy resin composition comprising: an epoxy resin, a photo-cationic polymerization initiator, and a compound represented by one of the following formulas (1) to (4)

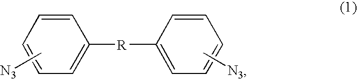

where R is —CH₂—, —O—, —S—, —CH═CH—, —N═N—, —SO₂—, >C═O—, —CH═CH—C(═O)—CH═CH—, —CH═CH—C(═O)—, or

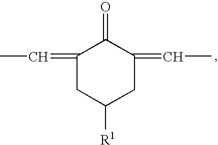

wherein R¹ is H or an alkyl group having 1 to 5 carbon atoms,

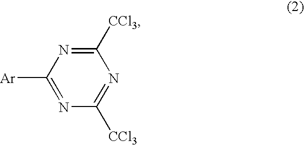

where Ar is an aryl group, such as a phenyl, a naphthyl, or a styryl group,

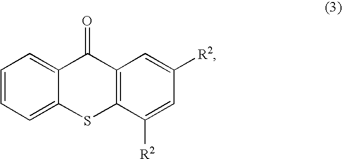

where each R² is independently selected from a hydrogen atom or an alkyl group selected from a methyl, an ethyl, and an isopropyl group, and

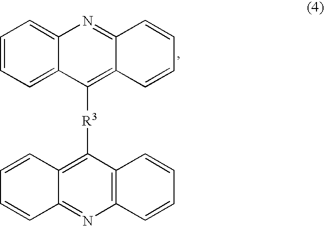

where R³ is an alkylene group having 1 to 20 carbon atoms, an oxadialkylene group, or a thiodialkylene group, and optionally has a side chain.

By using the photo-cationic polymerizable epoxy resin composition according to the present invention, a discharge port pattern having superior chemical resistance and mechanical strength can be formed. Moreover, this pattern is formed without dull foot corners even at a large film thickness of several micrometers to several tens of micrometers.

Furthermore, the liquid discharge head manufactured in accordance with the present invention has highly accurate flow paths, can discharge minute ink droplets, and can output a highly accurate image.

Additional features of the present invention will become apparent from the following description of exemplary embodiments with reference to the attached drawings.

### BRIEF DESCRIPTION OF THE DRAWINGS

FIG. 1 is a schematic perspective view showing an inkjet recording head according to an embodiment of the present invention.

FIGS. 2A to 2G are schematic cross-sectional views showing one example of a method for manufacturing an inkjet recording head according to an embodiment of the present invention.

FIG. 3 is a view illustrating a related technique.

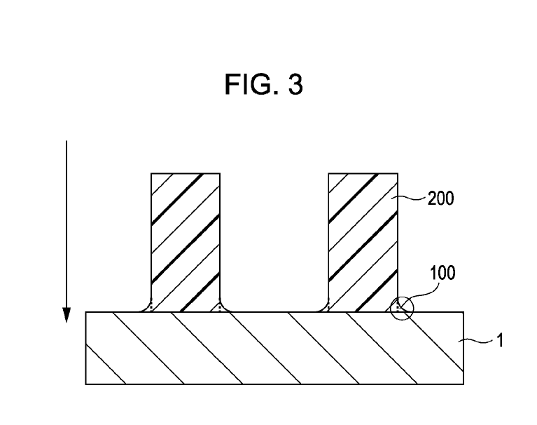

FIGS. 4A to 4F are schematic cross-sectional views each showing a part of an adhesion layer of an inkjet recording head according to an embodiment of the present invention.

### DETAILED DESCRIPTION OF THE INVENTION

A photo-cationic polymerizable epoxy resin composition according to the present invention and a method for manufacturing a liquid discharge head using the same are described below.

Photo-Cationic Polymerizable Epoxy Resin Composition

Epoxy Resin

A bisphenol A type epoxy resin or a novolac type epoxy resin, which is commonly known, may be used as an epoxy resin for a base material. In addition, epoxy resins having an oxycyclohexane backbone disclosed in U.S. Pat. Nos. 4,565,859, 5,580,695, and 4,841,017, Japanese Patent Laid-Open No. 2-140219, and the like may also be used. Among the resins mentioned above, polyfunctional epoxy resins having an oxycyclohexane backbone represented by the following structures (5) and (6) are preferably used:

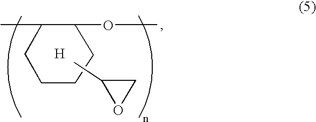

wherein n is a positive integer; and

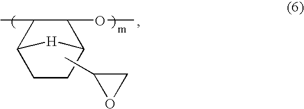

wherein m is a positive integer.

The above epoxy resins have a high cationic polymerizability as compared to that of a bisphenol A type epoxy resin and a novolac type epoxy resin. In addition, since a high cross-linking density can be easily obtained, a cured product having superior chemical resistance and mechanical strength can be obtained. Furthermore, since an aromatic ring is not incorporated in the structure, superior light transmission properties are obtained. Therefore, a product having a large thickness can be suitably used.

In addition, the epoxy equivalent of the above epoxy resin is preferably 2,000 or less and is more preferably 1,000 or less. When the epoxy equivalent is more than 2,000, since the cross-linking density obtained by curing reaction decreases, the deflection temperature or the glass transition temperature Tg of a cured product may decrease, and/or adhesion to a substrate and the chemical resistance may be disadvantageously reduced. Furthermore, in order to obtain superior patterning properties, the epoxy resin is preferably solid at room temperature.

Photo-Cationic Polymerization Initiator

An onium salt, a borate salt, a triazine compound, an azo compound, and a peroxide material are examples of compounds that may be used as the photo-cationic polymerization initiator. In view of the sensitivity, stability, reactivity, and solubility, an aromatic sulfonium salt and an aromatic iodonium salt are preferably used. As the aromatic sulfonium salt, for example, TPS-102, 103, and 105; MDS-103, 105, 205, and 305; and DTS-102 and 103 are commercially available from Midori Kagaku Co., Ltd. In addition, for example, SP-170 and 172 are also commercially available from Adeka Corp.

In addition, as the aromatic iodonium salt, for example, DPI-105; MPI-103 and 105; and BBI-101, 102, 103, and 105 are commercially available from Midori Kagaku Co., Ltd.

Among the compounds mentioned above, an appropriate compound may be selected in accordance with an exposure wavelength to be used. Furthermore, the addition amount may be arbitrarily determined in accordance with targeted sensitivity and cross-linking density, and in particular, the addition amount may be preferably set in the range of 0.1 to 7 percent by weight with respect to the epoxy resin.

A Polycyclic Aromatic Compound Including an Atom Having a Non-Covalent Electron Pair, which is Directly Bonded to an Aromatic Ring or which is Incorporated in a Heterocyclic Ring

The polycyclic aromatic compound including an atom having a non-covalent electron pair, which is directly bonded to an aromatic ring or which is incorporated in a heterocyclic ring, generally functions as a proton acceptor so as to decrease the function of an acid catalyst. In particular, the compounds represented by the following formulas (1) to (4) may be mentioned by way of example:

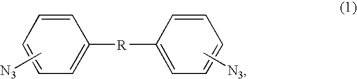

where R is —CH₂—, —O—, —S—, —CH═CH—, —N═N—, —SO₂—, >C═O—, —CH═CH—C(═O)—CH═CH—, —CH═CH—C(═O)—, or

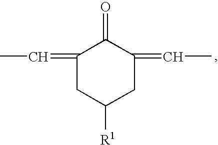

wherein R¹ is H or an alkyl group having 1 to 5 carbon atoms,

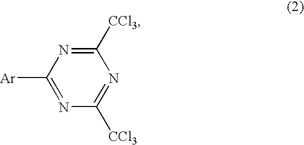

where Ar is an aryl group, such as a phenyl, a naphthyl, or a styryl group,

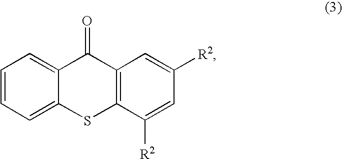

where each R² is independently selected from a hydrogen atom or an alkyl group selected from a methyl, an ethyl, and an isopropyl group (the R² substituents may be the same or may be different from each other),

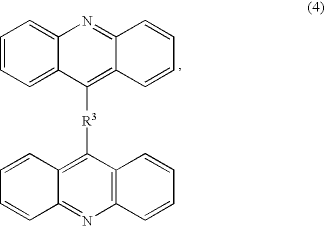

where R³ is an alkylene group having 1 to 20 carbon atoms, an oxadialkylene group, or a thiodialkylene group, and optionally has a side chain.

In addition, compounds containing an atom, such as nitrogen, sulfur, or phosphorus, may be mentioned in addition to the above compounds. Among these compounds, a nitrogen-containing compound and a sulfur-containing compound are preferable. Furthermore, in order to obtain a high resolution by the i-line exposure, a compound having absorption at a wavelength of approximately 365 nm is preferable.

As the nitrogen-containing compound, among a bisazide compound, a triazine compound, and an acridine compound, a solid compound is particularly preferable. In addition, as the sulfur-containing compound, among thioxanthone compounds, a solid compound may be used. As a particular example of the bisazide compound, compounds represented by the following formulas (7) to (17) may be mentioned:

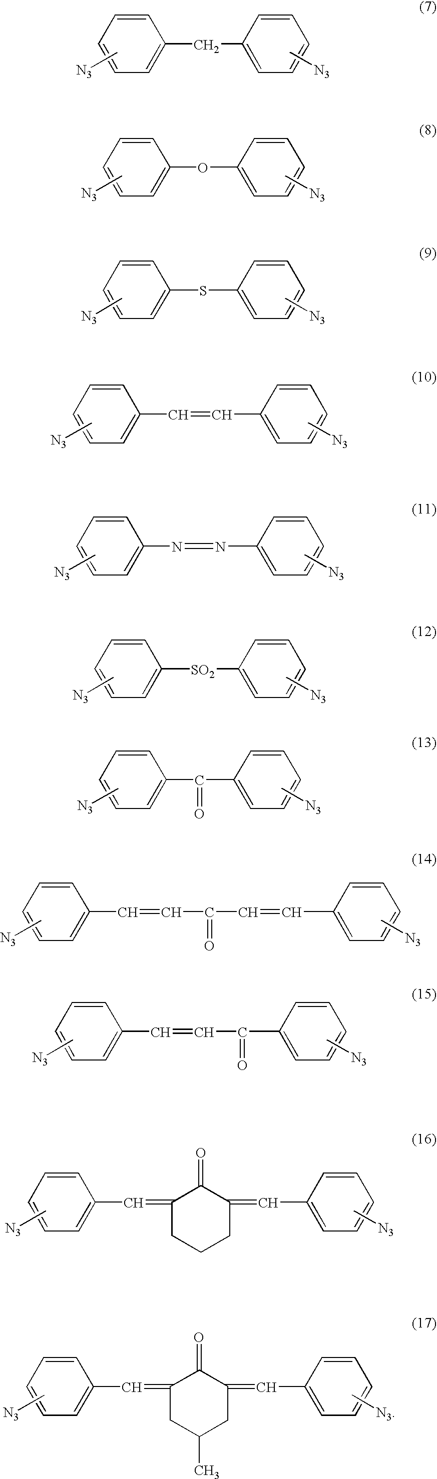

However, the bisazide compound is not limited to the above-listed examples.

As a particular example of a commercially available triazine compound, the following may be mentioned: TAZ-102, TAZ-104, TAZ-106, TAZ-108, TAZ-110, TAZ-113, TAZ-114, TAZ-118, and TAZ-123 (these are manufactured by Midori Kagaku Co., Ltd.). However, the triazine compound is not limited thereto.

The following are specific examples of the acridine compound. These examples include 1,2-bis(9-acridinyl)ethane, 1,3-bis(9-acridinyl)propane, 1,4-bis(9-acridinyl)butane, 1,6-bis(9-acridinyl)hexane, 1,7-bis(9-acridinyl)heptane, 1,8-bis(9-acridinyl)octane, 1,9-bis-(9-acridinyl)nonane, 1,10-bis(9-acridinyl)decane, 1,11-bis(9-acridinyl)undecane, 1,12-bis(9-acridinyl)dodecane, 1,14-bis(9-acridinyl)tetradecane, 1,16-bis(9-acridinyl)hexadecane, 1,18-bis(9-acridinyl)octadecane, 1,20-bis(9-acridinyl)eicosane, 1,3-bis(9-acridinyl)-2-thiapropane, and 1,5-bis(9-acridinyl)-3-thiapentane.

Among the compounds mentioned above, a compound in which an alkylene group (R³ in general formula 4) bonding two acridine rings has 6 to 12 carbon atoms is preferable in terms of photosensitivity and the like.

As a particular example of the thioxanthone compound, for example, there may be mentioned thioxanthene-9-one, isopropylthioxanthone, and 2,4-diethylthioxanthone However, the thioxanthone compound is not limited thereto.

The absorbance of the polycyclic aromatic compound including an atom having a non-covalent electron pair, which is directly bonded to an aromatic ring or which is incorporated in a heterocyclic ring, at 365 nm is adjusted by the addition amount so as to perform the taper control. In order to effectively form a taper having a superior shape, a method may be used in which the transmission of the resin film to an exposure wavelength is controlled so that a photoreaction initiated by the exposure is attenuated in the thickness direction. However, when the attenuation is excessively low, a taper having a superior shape cannot be formed. In addition, when the attenuation of the reaction is excessively high, the degree of curing inside a coating resin becomes insufficient toward the substrate surface, and as a result, the mechanical strength, ink resistance, adhesion to the substrate, and the like may be reduced.

Furthermore, it is preferable that polymerization inhibition caused by the above polycyclic aromatic compound be slight at an exposed portion so as to advance the polymerization reaction as much as possible, and that the function of the acid catalyst be sufficiently reduced at a non-exposed portion. Hence, in order to obtain targeted sensitivity and resolution properties, the addition amount must be adjusted.

Since the addition amount of the above polycyclic aromatic compound is dependent on its basicity and the absorbance of the film at a wavelength of 365 nm, it cannot be simply determined; however, with respect to the content of the photo-cationic polymerization initiator, the addition amount is preferably 0.1 to 7 percent by weight and more preferably 0.5 to 4 percent by weight. When the addition amount is small, a sufficient effect cannot be obtained at the unexposed portion. On the other hand, when the amount is excessively large, curing may not occur due to excessively high absorption, and/or curing at the exposed portion may be inhibited due to the basic properties of the addition compound.

When the curing is inhibited by the basic properties, the problem may be overcome by an increase in the exposure amount. However, since this will increase the exposure tact time, such an approach is not practical from the viewpoint of productivity.

Furthermore, at least two types of polycyclic aromatic compounds, each including an atom having a non-covalent electron pair, which is directly bonded to an aromatic ring or which is incorporated in a heterocyclic ring, are effectively mixed together so as to balance various properties.

Other Additives

For example, in order to increase the cross-linking density, to improve the coating properties, the water resistance, the solvent resistance, and the adhesion to the substrate, and to obtain the toughness, various additives may be added to the photo-cationic polymerizable epoxy resin composition of the present invention.

As described above, the photo-cationic polymerizable epoxy resin composition according to the present invention has the following features.

1. The addition of the polycyclic aromatic compound attenuates light exposure in the thickness direction, since absorption of the i-line occurs, for example, in a thick-film structure, such as an inkjet head, and the additive absorbs light. Consequently, the curing reaction of the resin caused by the light is attenuated along the film thickness direction, and hence, a tapered shape can be formed using a rectangular pattern. In addition, by adjusting the addition amount of the polycyclic aromatic compound, the extent to which the shape is tapered can also be controlled.

2. Since the polycyclic aromatic compound is a basic compound containing an atom having a non-covalent electron pair, the formation of dull foot corners caused by the diffusion of an acid along the pattern interface can be prevented, and hence, a desired rectangular pattern can be easily obtained.

3. Since it is in the form of a solid, the polycyclic aromatic compound is not as likely to evaporate as is a liquid compound. As a result, the manufacturing environment is not likely to be contaminated. In addition, compared to the liquid, the polycyclic aromatic compound is not likely to be influenced by moisture in the air, and hence, its stability is far superior (for example, in the case of using a liquid amine or the like, an oxide, such as an N-oxide, may be formed).

Method for Manufacturing a Liquid Discharge Head

Next, a method for manufacturing a liquid discharge head according to the present invention will be described in detail with reference to the drawings. Hereinafter, the same reference numerals designate constituent elements having the same functions as described above, and description thereof will be omitted in some cases.

According to the present invention, an inkjet recording system will be described as an application example of the liquid discharge head. However, it should be understood that the application of the present invention is not limited thereto, and that the present invention can also be applied to bio-chip formation, electronic circuit printing, and the like.

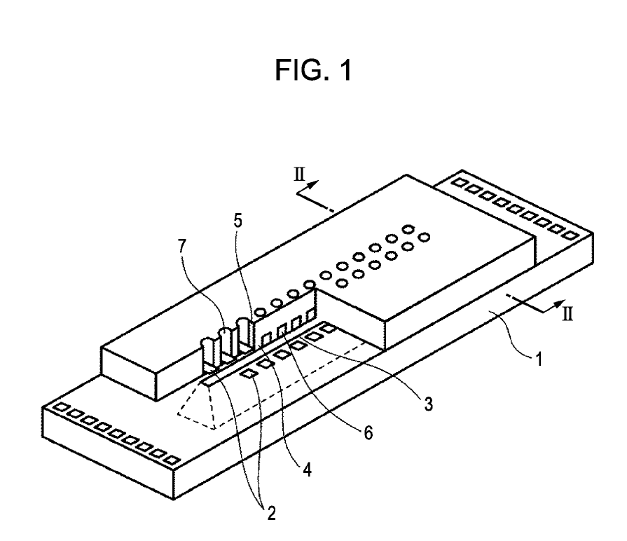

FIG. 1 is a schematic perspective view showing an inkjet recording head (hereinafter referred to as a “recording head”) of an embodiment according to the present invention. This recording head has a substrate 1 and energy generating elements 2, which generate energy used to discharge ink and which are formed on the substrate 1 at predetermined pitches. A supply port 3 supplying ink is provided in the substrate 1 between two lines of the energy generating elements 2. Discharge ports 5 provided on the substrate 1 above the respective energy generating elements 2 and ink flow paths 6 communicate with the ink supply port 3 via a flow path forming member 4.

In addition, the discharge ports 5 and the flow paths 6 communicate with each other through the respective discharge portions 7.

This recording head is disposed so that its surface, in which the discharge ports 5 are formed, faces a recording surface of a recording medium. This recording head discharges an ink droplet from the discharge port 5 by applying pressure generated by the energy generating element 2 to ink filled in the flow path 6 through the ink supply port 3, so that the discharged ink adheres to the recording medium to perform a recording operation.

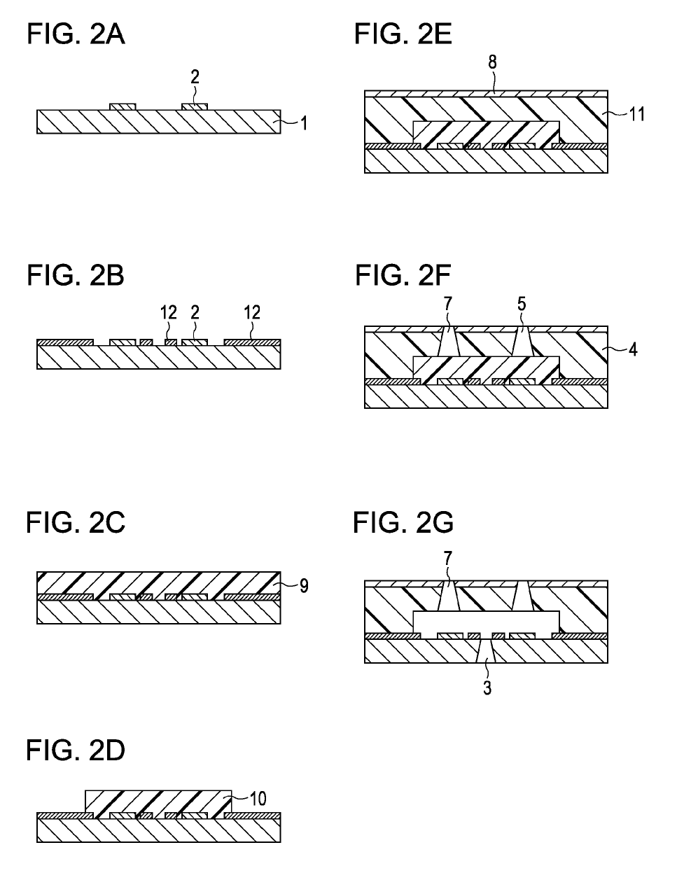

Next, the method for manufacturing a recording head according to the present invention will be described in detail with reference to FIGS. 2A to 2G.

FIGS. 2A to 2G are schematic cross-sectional views, each showing a recording head of one embodiment according to the present invention, viewed in a direction perpendicular to the substrate along the II-II line shown in FIG. 1.

First, as shown in FIG. 2A, the substrate 1 is prepared. As long as the substrate 1 functions as a part of the flow path forming member and also functions as a support for material layers forming the flow paths and the ink discharge ports, which are described below, the shape and the material of the substrate 1 are not particularly limited. In this embodiment, since the ink supply port 3 penetrating the substrate 1 is formed by anisotropic etching, which is described below, a silicon substrate is used. A desired number of electrothermal transducers or piezoelectric elements are disposed on the substrate 1 as the energy generating elements 2. As described above, energy is applied to ink by the energy generating elements 2 to discharge ink droplets, and as a result, make a recording. For example, when the electrothermal transducer is used as the above energy generating element 2 to discharge the ink, this element applies heat to a recording liquid in the vicinity thereof to generate a change in the state of the ink, so that discharge energy is generated. In addition, for example, when the piezoelectric element is used, discharge energy is generated by its mechanical vibration. In this embodiment, these energy generating elements are connected to control signal input electrodes (not shown) so as to be operated.

In addition, a protective layer (not shown) is generally provided in order to improve the durability of the energy generating element 2, and, in the present invention, the function layer as described above may also be provided.

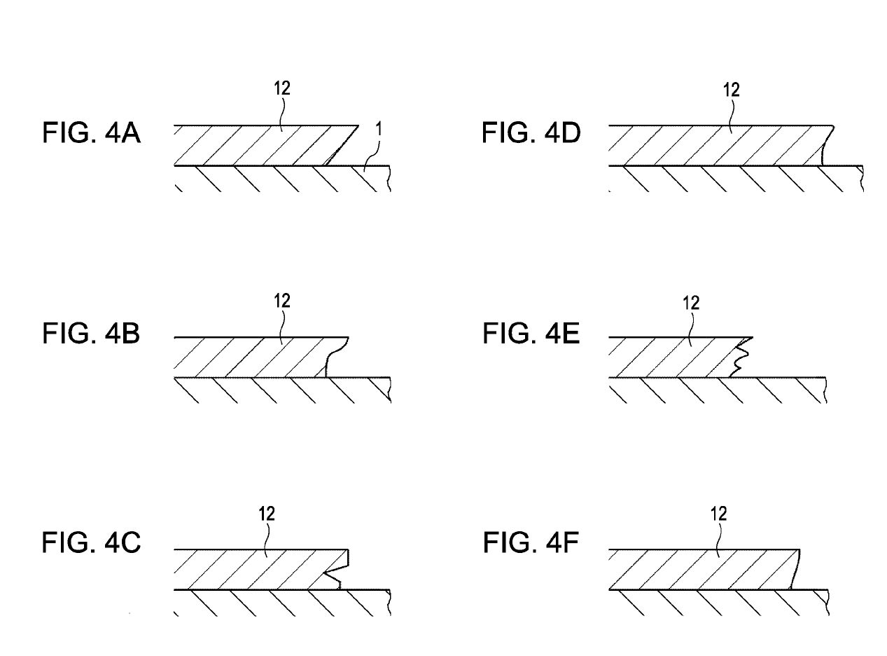

Next, as shown in FIG. 2B, an adhesion layer 12 is formed on the substrate 1 to improve the adhesion between the substrate and the flow path forming member. In the present invention, the adhesion layer is not always necessary; however, formation thereof may not cause any particular problem. Poly(ether amide) or photosensitive poly(ether amide) containing a cross-linking agent and a photo acid generator may be used as a material for the adhesion layer 12. Of course, other materials may also be used. In addition, although the pattern shape of the adhesion layer 12 is not particularly limited, an edge portion preferably has an overhang shape, as shown in FIGS. 4A to 4F (enlarged cross-sectional views similar to those shown in FIGS. 2A to 2G). This is because it is believed that when an exposure for forming the flow path forming member is performed, reflection of light by the substrate can be prevented. The overhang shape of the edge portion is shaped as described below. First, when the adhesion layer 12 provided on the substrate 1 is viewed from the side of the adhesion layer 12, the contact point between them cannot be observed. Next, as shown in FIGS. 2A to 2G and FIGS. 4A to 4F, when the cross-section of the adhesion layer 12 pattern is observed, the patterned end portion of the adhesion layer is present at its upper surface. It should be understood that the shape of the overhang portion is not limited to those described above, and that a shape in which the side surface of the edge portion of the adhesion layer can be observed when the adhesion layer 12 provided on the substrate 1 is viewed from the adhesion layer 12 side may also be used without causing any problems.

Next, as shown in FIG. 2C, a positive type photosensitive resin layer 9 is formed on the substrate 1.

Subsequently, as shown in FIG. 2D, the positive type photosensitive resin layer 9 is patterned by a photolithographic step, so that a pattern 10 used for forming the flow paths of ink is formed. Since the pattern 10 must be dissolved and removed in a subsequent step, a soluble positive type photosensitive resin is used. In particular, a vinylketone-based photodegradable polymeric compound, such as polymethyl isopropenyl ketone or polyvinylketone, or an acrylic photodegradable polymeric compound, is preferably used. In addition, a conventional solvent coating method, such as spin coating or slit coating, may be used to form the positive type resist layer.

Next, as shown in FIG. 2E, a negative type photosensitive resin layer 11 is formed on the substrate 1 provided with the pattern 10. In this step, spin coating, roll coating, split coating, or the like may be used. In addition, if necessary, an ink-phobic layer 8 having negative type photosensitivity is formed on the negative type photosensitive resin layer 11. The ink-phobic layer 8 can be formed by spin coating, roll coating, split coating, or the like. In this embodiment, since the ink-phobic layer 8 is formed on the uncured negative type photosensitive resin layer 11, the above two layers are preferably of a type that do not dissolve each other. The photo-cationic polymerizable epoxy resin composition described above can be preferably used as the negative type photosensitive resin layer 11.

Subsequently, as shown in FIG. 2F, pattern exposure is performed using a mask (not shown), and the pattern-exposed negative type resist 11 and ink-phobic layer 8 are developed using an appropriate solvent, so that the discharge portions 7 are formed. Exposure is performed using the i-line. In this case, the i-line is light having a single wavelength and is known as light having a central wavelength of 365 nm and a half bandwidth (full width at half maximum) of approximately 5 nm.

Next, as shown in FIG. 2G, after the ink supply port 3 is formed in the substrate 1, the pattern 10 is dissolved and removed. The ink supply port 3 may be formed, for example, using an excimer laser, a drill or by sand blasting or etching. By performing a heat treatment whenever necessary, the negative type resist 11 and the ink-phobic layer 8 are fully cured.

Furthermore, bonding of a member (not shown) used for the ink supply and the electrical connection for driving the energy generating elements are performed, so that the recording head is formed.

### EXAMPLES 1 AND 2

After resin compositions as shown in Table 1 were prepared and were then each applied (to have a thickness of 20 μm) on a silicon substrate, exposure using an i-line stepper was performed. In this step, the exposure amount was 5,000 J/m², and a pattern having an opening of 10 μm in diameter was obtained by patterning.

In addition, methyl isobutyl ketone was used as a coating solvent for the resin composition, and the solid concentrations of the materials shown in Table 1 were adjusted to 55%.

A series of steps from the application to the development through the exposure of the discharge port pattern (diameter of 10 μm) were sequentially performed for 100 substrates, and the ratio in the discharge port pattern dimension (diameter) of the 1^{st} substrate to the 100^{th} substrate was measured.

TABLE 1

| | | | | 10-μm diameter |
|---|---|---|---|---|
| | | Photo-cationic | | ratio of 1^{st}/100^{th} |
| Material | Epoxy resin composition | polymerization initiator | Basic additive | wafer |
| Example 1 | EHPE (Daicel Chemical | SP-172 (Adeka Corp.) | 2,6-bis(4′-azidobenzyl)-4- | 1 |
| | Industries Ltd.) | 5 percent by weight | methylcyclohexanone (A-106 | |
| | 100 percent by weight | | manufactured by Shinko | |
| | | | Technical Research Co., LTD.) | |
| | | | (Formula 18) | |
| | | | 2 percent by weight | |
| Example 2 | EHPE (Daicel Chemical | SP-172 (Adeka Corp.) | Thioxanthone (KAYACURE | 1 |
| | Industries Ltd.) | 5 percent by weight | DETX-S by Nippon Kayaku | |
| | 100 percent by weight | | Co., Ltd.) (Formula 19) | |
| | | | 2 percent by weight | |
| Comparative | EHPE (Daicel Chemical | SP-172 (Adeka Corp.) | Triethylamine | 0.92 |
| Example 1 | Industries Ltd.) | 5 percent by weight | 2 percent by weight | |
| | 100 percent by weight | | | |

Formula (18)

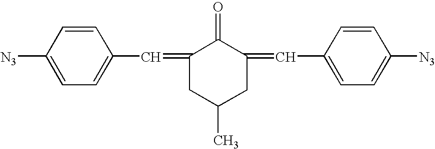

Formula (19)

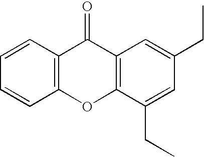

As a result, no change in the pattern dimension between the 100^{th} and the 1^{st} wafers was observed in Examples 1 and 2 in which 2,6-bis(4′-azidobenzyl)-4-methylcyclohexanone (formula 18) and thioxanthone (formula 19) were used, respectively. However, in Comparative Example 1, in which triethylamine was used, degradation in sensitivity, which might be caused by environmental contamination, occurred in some cases. Specifically, the size of the discharge port of the 100^{th} wafer was unfavorably increased. In particular, the ratio in diameter of the discharge port of the 1^{st} wafer to that of the 100^{th} wafer was 0.92. The reason for this is believed to be that while 2,6-bis(4′-azidobenzyl)-4-methylcyclohexanone and thioxanthone, which were used in Examples 1 and 2, respectively, are solid at room temperature, triethylamine used in Comparative Example 1 was in the form of a liquid, which led to the formation of triethylamine vapor during the manufacturing process, adversely influencing the exposure.

### EXAMPLE 3

In this Example, the recording head was formed by the steps shown in FIGS. 2A to 2G.

First, electrothermal transducers (heater made from HfB₂) used as the energy generating elements 2 and the silicon substrate 1 partly provided with an SiN and Ta laminate film (not shown) were prepared (FIG. 2A).

Next, poly(ether amide) sold under the trade name HIMAL 1200, manufactured by Hitachi Chemical Co., Ltd., was applied on the substrate 1 by a spinner to form the adhesion layer 12 having a thickness of 2.0 μm. Baking was performed in a step-wise manner at 100° C. for 30 minutes and 250° C. for 1 hour. Subsequently, a film of FH-SP (positive type resist manufactured by Fuji Film Olin Co., Ltd., now known as FUJIFILM Electronic Materials Co., Ltd.) was formed on the poly(ether amide) layer, followed by patterning. In addition, by using the FH-SP pattern as a mask, the poly(ether amide) was patterned by O₂ plasma ashing, and finally, the FH-SP used as the mask was ashed away by CF₄ plasma, so that the adhesion layer 12 was formed. By the use of a resist having superior oxygen plasma resistance, such as FH-SP, the thickness of the resist mask could be decreased, and when over-etching was performed by increasing the etching time, a HIMAL film having an overhang shape could be obtained. When the cross-section of the adhesion layer pattern was observed using a scanning electron microscope, the shape as shown in FIG. 4A was obtained. An inverted tapered shape having an angle of 80° between the substrate surface and the side surface of the adhesion layer was obtained (FIG. 2B).

Next, the pattern 10 for the flow paths was formed on the substrate 1 using a copolymer of methacrylic acid and methyl methacrylate (the ratio of methyl methacrylate to methacrylic acid: 90 to 10, Mw: 80,000, and Mn: 2.5) (FIG. 2D).

Then, a photosensitive resin composition including the following materials was spin-coated (a thickness of 20 μm on the plate) on the pattern 10 and then baked at 100° C. for 2 minutes (by a hot plate), so that the negative type photosensitive resin 11 used for the flow path forming member was cured.

| | |
|---|---|
| EHPE (manufactured by Daicel Chemical | 50 percent by weight |
| Industries Ltd.) | |
| 1,4-HFAB (manufactured by Central Glass Co., | 10 percent by weight |
| Ltd.) | |
| SP-172 (manufactured by Adeka Corp.) | 1 percent by weight |
| 2,6-bis(4′-azidobenzyl)-4-methylcyclohexanone | 0.5 percent by weight |
| (Formula 18) | |
| (A-016 manufactured by Shinko Technical | |
| Research Co., LTD.) | |
| Methyl Isobutyl Ketone | 19.25 percent by weight |
| Diglyme | 19.25 percent by weight |

Subsequently, on the substrate 1, the ink-phobic layer 8 having photosensitivity was formed to have a thickness of 1 μm.

Next, the negative type resist 11 and the ink-phobic layer 8 were patterned using an i-line stepper to form the discharge portions 7 and, in addition, to form the flow path forming member 4 (FIG. 2F). Also, in this Example, the discharge ports 5 having an opening (diameter) of 10 μm were formed.

Subsequently, the ink supply port 3 was formed by anisotropic etching of the silicon substrate. In this step, in order to protect the ink-phobic layer 8 from an etching solution, a protective film (not shown (OBC manufactured by Tokyo Ohka Kogyo Co., Ltd.)) was formed on the ink-phobic layer 8. Next, after OBC was dissolved and removed by using xylene, the entire surface was exposed through the flow path forming member 4 and the ink-phobic layer 8 using light having a wavelength of 200 to 280 nm at an exposure amount of 80,000 mJ/cm², so that the ink flow path pattern 10 was made soluble. Next, the substrate 1 thus processed was immersed in a methyl lactate solution while being subjected to ultrasonic waves so as to remove the flow path pattern 10, thereby forming the recording head (FIG. 2G).

In order to confirm the quality of the recording head thus formed, the ink flow path shape was first observed using a metallographic microscope and a scanning electron microscope. Since the flow path forming member 4 and the ink-phobic layer 8 of the recording head according to this Example were colorless and transparent, the shape of the ink flow path could be observed by a metallographic microscope. As a result, no deformed flow paths 6 were observed. In addition, when the cross-section of the flow path 6 was observed by a scanning electron microscope, the generation of scum along the flow paths 6 was reduced so as to be hardly visible. The discharge portion 7 was formed to have a superior tapered shape (such that the area thereof parallel to the substrate 1 gradually decreased toward the discharge port 5).

Furthermore, after the recording head was fitted in a recording device, when printing was performed using an ink containing pure water/glycerin/Direct Black 154 (water soluble black dye) at a ratio of 65/30/5, the initial printing was superior. In addition, image printing could also be steadily performed.

In addition, when nozzles were manufacturing by sequentially processing 50 silicon wafers, no change in discharge port diameter was observed in any of the wafers thus processed. Also, no degradation in the sensitivity of the resist, which might be caused by environmental contamination due to the evaporation of a basic material, was observed. Furthermore, the stability of the material was also superior, and even when nozzles were manufactured using a resin composition that was prepared one month before as a sample, no variation in discharge port diameter was observed.

### EXAMPLE 4

As the negative type photosensitive resin 11, the following photo-cationic polymerizable epoxy resin composition was used. In addition, the adhesion layer was formed by the method described below. The recording head was formed in the same manner as that described in Example 1.

| | | |
|---|---|---|
| Photo-cationic polymerizable epoxy resin composition | 50 | percent by weight |
| EHPE (manufactured by Daicel Chemical Industries Ltd.) | | |
| 1,4-HFAB (manufactured by Central Glass Co., Ltd.) | 10 | percent by weight |
| SP-172 (manufactured by Adeka Corp.) | 1 | percent by weight |
| TAZ-110 (Formula 19) (manufactured by Midori Kagaku Co., | 0.5 | percent by weight |
| Ltd.) | | |
| Methyl Isobutyl Ketone | 19.25 | percent by weight |
| Diglyme | 19.25 | percent by weight |
| Formula 19 | | |
| 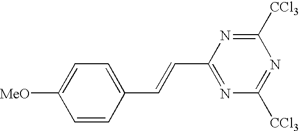 | | |
| Compound used for the adhesion layer 12: | | |
| Poly(ether amide) resin having the following repeating unit | 20 | percent by weight |
| and a molecular weight Mw of 25,000 | | |

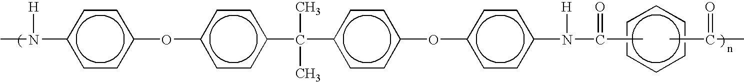

| | | |
|---|---|---|
| Cross-linking agent; hexamethoxymethylmelamine E-2151 | 2 | percent by weight |
| (manufactured by Sanwa Chemical Co., Ltd.) | | |
| Photo polymerization initiator Sp-172 (manufactured by Adeka | 0.5 | percent by weight |
| Corp.) | | |
| N-methyl-2-pyrollidone (NMP) | 77.5 | percent by weight |

The compound described above was applied on the substrate 1 using a spinner and was then baked in a step-wise manner at 100° C. for 30 minutes and 250° C. for one hour. Next, by an i-line stepper FPA-3000 manufactured by Canon Kabushiki Kaisha, patterning was performed at an exposure amount of 10,000 J/m², followed by heating using a hot plate at 140° C. for 3 minutes. Subsequently, development was performed using a mixed solvent containing propylene glycol monomethyl ether acetate and triglyme, so that the adhesion layer 12 was formed. In this Example, when the pattern cross-section of the adhesion layer 12 was observed, an overhang pattern was obtained.

When the cross-section of the recording head thus formed was observed by a scanning electron microscope, the generation of scum along the flow paths 6 was reduced so as to be hardly visible, and the discharge portion was formed to have a superior tapered shape. Furthermore, after the recording head was fitted in a recording device, when printing was performed using an ink containing pure water/glycerin/Direct Black 154 (water soluble black dye) at a ratio of 65/30/5, the initial printing was superior. In addition, image printing could also be steadily performed. Also, when nozzles were manufactured by sequentially processing 50 silicon wafers, no change in discharge port diameter was observed in any of the wafers thus processed. No degradation in sensitivity of the resist, which might be caused by environmental contamination due to a basic material, was observed. Furthermore, the stability of the material was also superior, and even when nozzles were manufactured using a resin composition prepared one month before as a sample, no variation in discharge port diameter was observed.

While the present invention has been described with reference to exemplary embodiments, it is to be understood that the invention is not limited to these exemplary embodiments. The scope of the following claims is to be accorded the broadest interpretation so as to encompass all modifications, equivalent structures and functions.

This application claims the benefit of Japanese Application No. 2006-346267, filed Dec. 22, 2006, which is hereby incorporated by reference herein in its entirety.

What is claimed is:

1. A method for manufacturing a liquid discharge head having: a substrate provided with energy generating elements for generating energy to discharge a liquid; discharge portions including discharge ports for discharging the liquid; and flow paths supplying the liquid to the discharge portions, the method comprising the steps of:
forming a layer of a negative type photosensitive resin on the substrate; and
exposing the layer to light having a wavelength of 365 nm to form the discharge portions,
wherein the negative type photosensitive resin comprises an epoxy resin, a photo-cationic polymerization initiator, and a polycyclic aromatic compound comprising an atom having a non-covalent electron pair, which is directly bonded to an aromatic ring or which is incorporated in a heterocyclic ring.

2. The method according to claim 1, wherein the atom having the non-covalent electron pair is a nitrogen atom or a sulfur atom, and the polycyclic aromatic compound is a basic compound.

3. The method according to claim 1, wherein the polycyclic aromatic compound is represented by one of formulas (1) to (4) 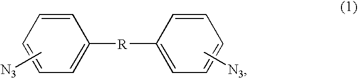
where R is —CH₂—, —O—, —S—, —CH═CH—, —N═N—, —SO₂—, >C═O—, —CH═CH—C(═O)—CH═CH—, —CH═CH—C(═O)—, or 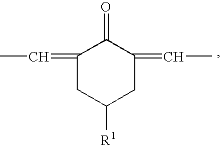
wherein R¹ an alkyl group having 1 to 5 carbon atoms, 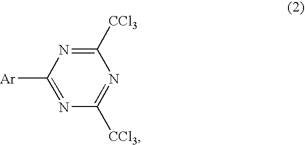
where Ar is an aryl group, 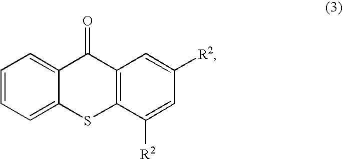
where each R² is independently selected from a hydrogen atom and an alkyl group selected from the group consisting of a methyl group, an ethyl group, and an isopropyl group, and 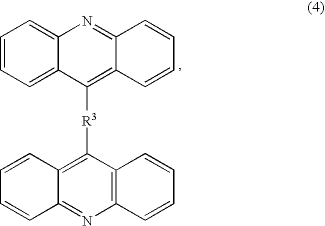
where R³ is an alkylene group having 1 to 20 carbon atoms, an oxadialkylene group, or a thiodialkylene group, and optionally has a side chain.

4. The method according to claim 1, wherein the epoxy resin has a structure represented by formula (5) or (6) 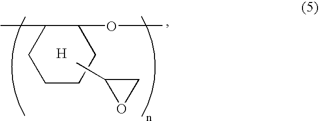
where n is a positive integer, or 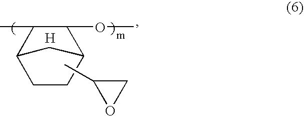
where m is a positive integer.

5. The method according to claim 1, wherein the discharge ports are formed to face the energy generating elements, and the discharge portions are tapered toward the discharge ports.

6. The method according to claim 1, wherein the layer is formed on a pattern for the flow paths, which are formed on the substrate from a soluble resin.

7. A photo-cationic polymerizable epoxy resin composition comprising: an epoxy resin, a photo-cationic polymerization initiator, and a compound represented by one of (1) to (4) 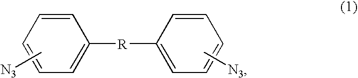
where R indicates —CH₂—, —O—, —S—, —CH═CH—, —N═N—, —SO₂—, >C═O—, —CH═CH—C(═O)—CH═CH—, —CH═CH—C(═O)—or 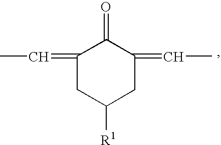
wherein R¹ is H or an alkyl group having 1 to 5 carbon atoms, 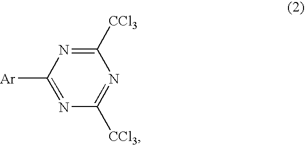
where Ar is an aryl group, 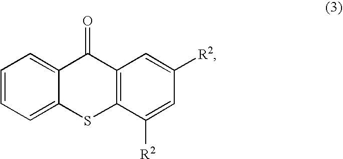
where each R² is independently selected from a hydrogen atom and an alkyl group selected from the group consisting of a methyl group, an ethyl group, and an isopropyl group, and 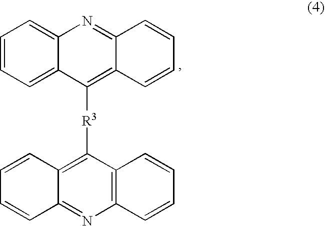
where R³ is an alkylene group having 1 to 20 carbon atoms, an oxadialkylene group, or a thiodialkylene group, and optionally has a side chain.

8. The photo-cationic polymerizable epoxy resin composition according to claim 7, wherein the epoxy resin has a structure represented by formula (5) or (6) 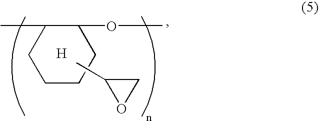
where n is a positive integer, or 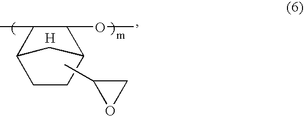
where m is a positive integer.

9. The photo-cationic polymerizable epoxy resin composition according to claim 7, wherein the photo-cationic polymerization initiator is an aromatic sulfonium salt and/or an aromatic iodonium salt.

10. A liquid discharge head comprising:
energy generating elements for generating energy to discharge a liquid;
discharge portions having discharge ports for discharging the liquid; and
flow paths supplying the liquid to the discharge portions,
wherein a cured product of the photo-cationic polymerizable epoxy resin composition according to claim 7 forms a flow path forming member from which the flow paths are formed.

11. The liquid discharge head according to claim 10, wherein the discharge ports face the energy generating elements, and the discharge portions are tapered toward the discharge ports.
